(19) United States
(12) Patent Application Publication
(10) Pub. No.: US 2020/0235560 A1
(43) Pub. Date: Jul. 23, 2020

(54) CABLE DRUM

(71) Applicant: Fujikura Ltd., Tokyo (JP)

(72) Inventor: Kenji Takahashi, Sakura-shi (JP)

(73) Assignee: Fujikura Ltd., Tokyo (JP)

(21) Appl. No.: 16/639,682

(22) PCT Filed: Jan. 17, 2019
(86) PCT No.: PCT/JP2019/001329

§ 371 Date: Feb. 17, 2020

(30) Foreign Application Priority Data
Jan. 18, 2018 (JP) 2018-006601

(51) Int. Cl. H02G 11/02; B65H 75/14; F16L 3/01; H05K 7/20

(52) U.S. Cl. CPC H02G 11/02; B65H 75/14; B65H 2701/528; H05K 7/20336; F16L 3/012

(57) ABSTRACT

A cable drum, around which a cable is coiled, includes: a body; a flange; a cable coiled around the body; and a plurality of heat pipes arranged across the body and the flange. Evaporating portions of the plurality of heat pipes are disposed in the body. Condensing portions of the plurality of heat pipes are disposed in the flange.

### CROSS-REFERENCE TO RELATED APPLICATIONS

This application is a continuation application of International Patent Application No. PCT/JP2019/001329, filed on Jan. 17, 2019, which claims priority to Japanese Patent Application No. 2018-006601, filed on Jan. 18, 2018. These references are incorporated herein by reference in their entirety.

### TECHNICAL FIELD

The present invention relates to a cable drum.

### BACKGROUND

A cable drum as indicated in Patent Literature 1 below is known conventionally. This cable drum is used by being connected to a blower or the like. A hole is provided in a body portion of the cable drum and air for air cooling is sent into the body portion through the hole to cool a power cable wound around the body portion.
[Patent Literature 1] Japanese Patent No. 2910941

In the constitution of Patent Literature 1 mentioned above, it is necessary to connect a blower or the like in order to cool the power cable. For this reason, there is room for improvement from the viewpoints of downsizing of the whole apparatus, enhancement of portability, cost reduction, and the like.

### SUMMARY

Embodiments of the present invention provide a cable drum capable of efficiently cooling a cable wound around a body portion without using a blower or the like.

A cable drum according to one or more embodiments is a cable drum having a body portion and a flange portion, in which a cable is coiled around the body portion, the cable drum including a plurality of heat pipes arranged across the body portion and the flange portion, in which evaporating portions of the heat pipes are disposed in the body portion, and condensing portions of the heat pipes are disposed in the flange portion.

According to one or more embodiments, the evaporating portions of the heat pipes are disposed in the body portion of the cable drum, and the condensing portions of the heat pipes are disposed in the flange portion of the cable drum. With this structure, when the cable wound around the body portion generates heat, the heat of the body portion can be efficiently transferred to the flange portion by the heat pipes. In addition, it is possible to efficiently dissipate the transferred heat from the flange portion. Therefore, it is possible to efficiently cool the wound cable without connecting, for example, a blower.

Here, the flange portion may have a heat dissipation flange portion to which the condensing portions are fixed, and the body portion and the heat dissipation flange portion may be separated.

When heat is applied to an intermediate portion between the evaporating portion and the condensing portion in the heat pipe, there is a possibility of a phenomenon in which a working fluid evaporates at this intermediate portion and unexpectedly backflows to the evaporating portion side occurring.

Thus, by arranging the body portion and the heat dissipation flange portion apart from each other, it is possible to suppress the application of heat to the intermediate portion of the heat pipe and to restrain the occurrence of the above phenomenon.

In addition, the flange portion may have a cable flange portion fixed to the body portion and extending to an outer side in a radial direction from the body portion, and the heat dissipation flange portion and the cable flange portion may be separated in an axial direction.

In this case, the cable flange portion requiring strength and the heat dissipation flange portion requiring heat dissipation properties are set as independent bodies and the respective requirements can be satisfied.

In addition, the flange portion may have a heat dissipation flange portion to which the condensing portions are fixed, and a plurality of groove portions extending in a circumferential direction may be formed in the heat dissipation flange portion.

In this case, by enlarging the surface area of the heat dissipation flange portion, the heat transported from the evaporating portion to the condensing portion of the heat pipe can be efficiently released from the heat dissipation flange portion. Furthermore, when the cable drum is rotated about the center axis of the body portion, heat can be dissipated efficiently by the air traveling through the groove portions extending in the circumferential direction.

In addition, the flange portion may have a heat dissipation flange portion to which the condensing portions are fixed, and a plurality of groove portions extending in a radial direction may be formed in the heat dissipation flange portion.

In this case, by enlarging the surface area of the heat dissipation flange portion, the heat transported from the evaporating portion to the condensing portion of the heat pipe can be efficiently released from the heat dissipation flange portion. Furthermore, when the cable drum is rotated about the center axis of the body portion, the air surrounding the heat dissipation flange portion is agitated by the groove portions extending in the radial direction. Therefore, the heat dissipation efficiency can be further raised.

According to one or more embodiments of the present invention, it is possible to provide a cable drum capable of efficiently cooling a cable wound around a body portion without using a blower or the like.

### BRIEF DESCRIPTION OF DRAWINGS

FIG. 1 is a cross-sectional view of a cable drum according to one or more embodiments.

FIG. 2A is a view in arrow direction A in FIG. 1.

FIG. 2B is a cross-sectional view in an arrow direction taken along line B-B in FIG. 1.

FIG. 3A is a view illustrating a modified example of one or more embodiments in which a plurality of groove portions extending in a circumferential direction are formed in a heat dissipation flange portion.

FIG. 3B is a view illustrating a modified example of one or more embodiments in which a plurality of groove portions extending in a radial direction are formed in a heat dissipation flange portion.

### DETAILED DESCRIPTION

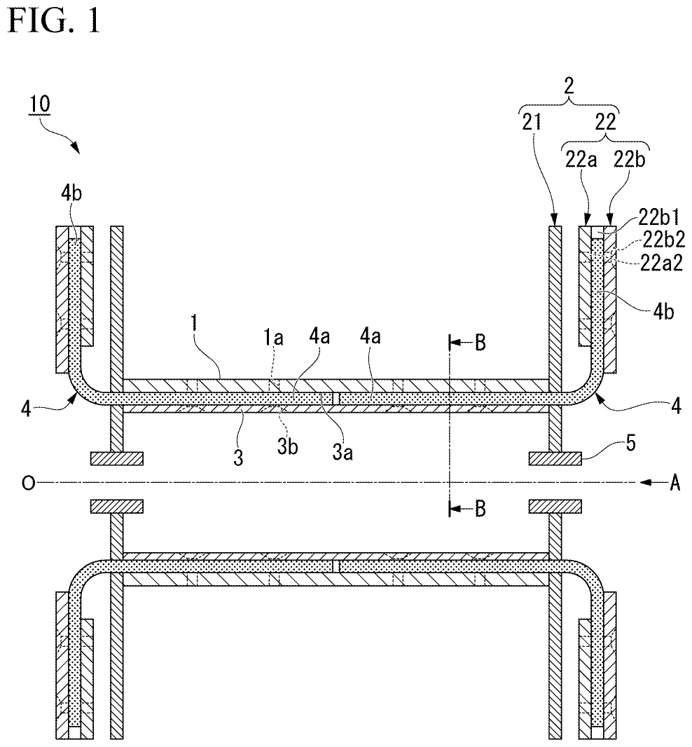

Hereinafter, a cable drum 10 according to one or more embodiments will be described with reference to FIGS. 1 to 3B.

As illustrated in FIG. 1, the cable drum 10 has a body portion 1 (body) and a pair of flange portions 2 (flanges). The body portion 1 is cylindrical and the pair of flange portions 2 are arranged at two respective end portions of the body portion 1. The diameter of the body portion 1 is, for example, about 300 mm.

A cable for power supply or the like (hereinafter simply referred to as a cable) is coiled around the body portion 1. When the cable is energized while the cable is wound around the body portion 1, the cable generates heat. Accordingly, it is necessary to cool the cable. In particular, in the case of a high voltage or a large current, since the heat generation amount of the cable is increased, it is necessary to efficiently cool the body portion 1.

Furthermore, the cable drum 10 can be rotated about a center axis O of the body portion 1 in order to feed out the cable wound around the body portion 1 and to draw out the wound cable. For example, the cable drum 10 is installed on a drum shaft (not illustrated) of a feeder machine so as to rotate integrally with the drum shaft. By rotating the drum shaft about the center axis O, the cable can be wound up around the body portion 1 of the cable drum 10. In addition, by rotating the drum shaft in the reverse direction, the wound-up cable can be fed out.

### (Definitions of Directions)

In one or more embodiments, a direction along the center axis O is referred to as an axial direction. In addition, a direction intersecting the center axis O when seen in the axial direction is referred to as a radial direction, whereas a direction along a circumference about the center axis O is referred to as a circumferential direction. Furthermore, a side on which the body portion 1 is located in the axial direction when seen from the flange portions 2 is referred to as an inner side in the axial direction, and the opposite side is referred to as an outer side in the axial direction.

### (Heat Pipe)

The cable drum 10 includes a plurality of heat pipes 4 arranged across the body portion 1 and the flange portions 2. Each heat pipe 4 has an evaporating portion 4a extending in the axial direction and a condensing portion 4b extending in the radial direction. The evaporating portion 4a is disposed in the body portion 1, and the condensing portion 4b is disposed in one of the flange portions 2. The evaporating portion 4a extends toward the outer side in the axial direction from a center portion in the axial direction of the body portion 1. The condensing portion 4b extends toward the outer side in the radial direction from an end portion on the outer side in the axial direction of the evaporating portion 4a. In one or more embodiments, each heat pipe 4 is formed in an L shape, and the evaporating portions 4a of two adjacent heat pipes 4 in the axial direction oppose each other in the vicinity of the center portion in the axial direction of the body portion 1. The two opposing heat pipes 4 are denoted as a pair, namely, a heat pipe pair. A plurality of heat pipe pairs are arranged at equal intervals in the circumferential direction.

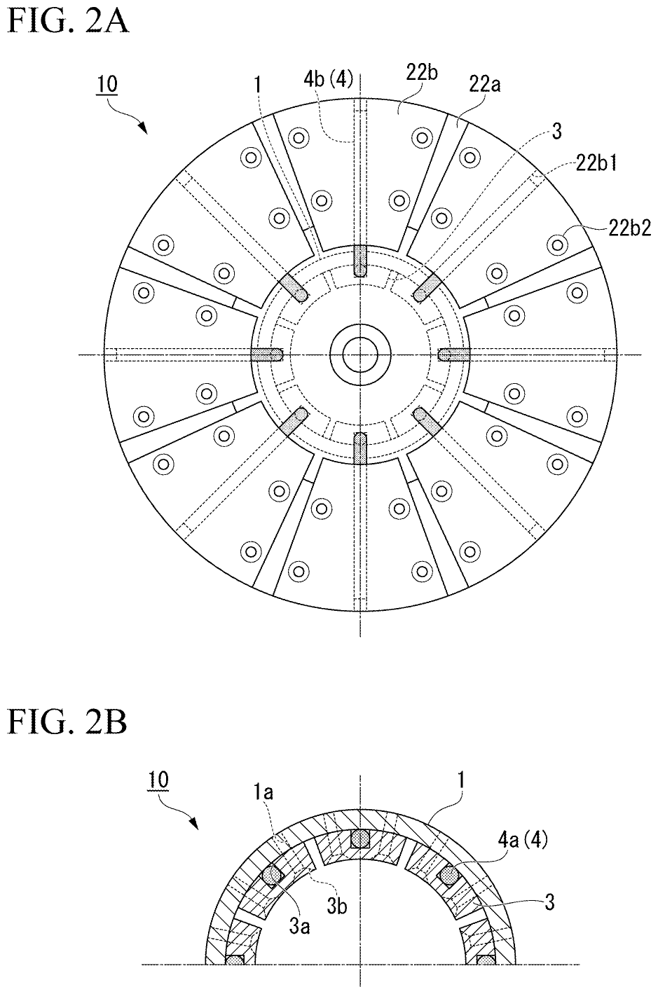

As illustrated in FIG. 2, in the cable drum 10 of one or more embodiments, eight heat pipe pairs are arranged at equal intervals in the circumferential direction. In this case, the heat pipe pairs are arranged at intervals of 45° in the circumferential direction. The diameter of each heat pipe 4 is, for example, 8 mm Note that the number and the diameter of the heat pipes 4 to be disposed may be appropriately changed according to the heat generation amount of the cable.

The heat pipe 4 has a container, and a wick and a working fluid enclosed in the container.

The container is, for example, a sealed pipe having a hollow inside. The material of the container can be appropriately selected depending on the conditions such as the type of the working fluid and the operating temperature. In particular, when a metallic substance having high heat conductivity, such as copper or aluminum, is used, heat transportability and thermal diffusibility can be raised. The container can be formed using a metal tube such as a copper tube, an aluminum tube, or a stainless steel tube.

The wick is arranged in the container in an extending direction of the heat pipe 4. As the material of the wick, for example, a sintered body (porous sintered body) of a metal fine wire fiber, a metal mesh, a metal powder, or the like can be used. A large number of pores for generating capillary force are formed inside the wick.

The working fluid is a fluid which is caused to evaporate by heating and caused to condense by heat dissipation. The type of the working fluid can be appropriately selected according to the temperature at which the heat pipe 4 is used, and the like. As the working fluid, for example, water, an alcohol, an alternative chlorofluorocarbon (CFC), or the like can be used.

The interior space of the container functions as a flow path through which the gas-phase working fluid moves from the side of the evaporating portion 4a to the side of the condensing portion 4b, and heat is transported from the side of the evaporating portion 4a to the side of the condensing portion 4b through mass transfer of the gas-phase working fluid. The wick has a function of refluxing the working fluid condensed in the condensing portion 4b to the side of the evaporating portion 4a by a capillary phenomenon and sustaining the action of the heat pipe 4.

In this manner, the heat pipe 4 can continue to transport heat from the high-temperature portion side to the low-temperature portion side.

### (Body Portion)

The body portion 1 is formed in a cylindrical shape and a cable is coiled around an outer circumferential surface of the body portion 1. In order to cool the coiled cable, the evaporating portion 4a of the heat pipe 4 is disposed in the body portion 1. In one or more embodiments, the evaporating portion 4a of the heat pipe 4 is in abutment with or proximity to an inner circumferential surface of the body portion 1.

In one or more embodiments, the evaporating portion 4a of each heat pipe 4 is fixed to the body portion 1 with a fixing plate 3 so as to contact the body portion 1. As illustrated in FIGS. 2A and 2B, the fixing plate 3 is formed in an arc shape when seen in the axial direction. An evaporating portion groove 3a and a plurality of countersunk holes 3b are formed in the fixing plate 3.

The evaporating portion groove 3a is a groove for accommodating the evaporating portion 4a of the heat pipe 4. The evaporating portion groove 3a is recessed toward the inner side in the radial direction from an outer circumferential surface of the fixing plate 3. The evaporating portion groove 3a has a width and a depth equivalent to the diameter of the heat pipe 4. The evaporating portion groove 3a extends over the entire length of the fixing plate 3 in the axial direction.

The countersunk holes 3b go through the fixing plate 3 in the radial direction. The countersunk holes 3b are formed such that screws can be inserted from the inner side in the radial direction. The screws are screwed into screw holes 1a formed in the body portion 1, whereby the fixing plate 3 and the heat pipe 4 are fixed to the body portion 1. Note that the fixing method for the heat pipe 4 can be appropriately changed. For example, the fixing plate 3 or the heat pipe 4 may be fixed to the body portion 1 by adhesion or welding. Furthermore, the heat pipe 4 may be fixed without using the fixing plate 3.

### (Flange Portion)

The flange portions 2 are located at two end portions in the axial direction of the body portion 1 and each is constituted by a cable flange portion 21 and a heat dissipation flange portion 22.

The cable flange portion 21 is formed in a ring shape when seen in the axial direction. The cable flange portions 21 are fixed to the body portion 1 and extend toward the outer side in the radial direction from the two end portions in the axial direction of the body portion 1. The cable flange portions 21 have a function of preventing winding collapse of the cable accumulated and wound around the outer circumference of the body portion 1.

An attachment member 5 for attaching the cable drum 10 to the above-described drum shaft is disposed at an end portion on the inner side in the radial direction of the cable flange portion 21. As the attachment member 5, a bearing or the like can be used. Note that the attachment member 5 may be provided on the body portion 1 or the like.

The heat dissipation flange portion 22 is formed in a ring shape when seen in the axial direction and has an outer diameter equivalent to the outer diameter of the cable flange portion 21. The heat dissipation flange portion 22 is disposed on the outer side in the axial direction of the cable flange portion 21. The condensing portion 4b of the heat pipe 4 is fixed to the heat dissipation flange portion 22. The heat dissipation flange portion 22 serves to receive heat from the condensing portion 4b of the heat pipe 4 and release the received heat from the surface of the heat dissipation flange portion 22. For this reason, a material having low thermal resistance such as aluminum is suitable as the heat dissipation flange portion 22.

The heat dissipation flange portion 22 of one or more embodiments is constituted by an inner member 22a and a plurality of outer members 22b. The condensing portion 4b of the heat pipe 4 is fitted between the inner member 22a and the outer members 22b in the axial direction. The inner member 22a is located on the inner side in the axial direction of the outer members 22b.

The inner member 22a is formed in a ring shape when seen in the axial direction. The inner diameter of the inner member 22a is larger than the outer diameter of the body portion 1. The plurality of outer members 22b have shapes obtained by equally dividing a ring in the circumferential direction when seen in the axial direction. The inner diameter of the outer members 22b is smaller than the inner diameter of the inner member 22a. A condensing portion groove 22b1 and a plurality of countersunk holes 22b2 are formed in each outer member 22b.

The condensing portion groove 22b1 is a groove for accommodating the condensing portion 4b of the heat pipe 4. The condensing portion groove 22b1 is recessed toward the outer side in the axial direction from the inner side surface in the axial direction of the outer members 22b. The condensing portion groove 22b1 has a width and a depth equivalent to the diameter of the heat pipe 4. The condensing portion groove 22b1 extends over the entire length of the outer member 22b in the radial direction.

The countersunk holes 22b2 go through the outer member 22b in the axial direction. The countersunk holes 22b2 are formed such that screws can be inserted from the outer side in the axial direction. By screwing these screws into screw holes 22a2 formed in the inner member 22a, the condensing portion 4b of the heat pipe 4 is fixed while being sandwiched between the inner member 22a and the outer members 22b. Note that the fixing method for the condensing portion 4b can be appropriately changed. For example, the outer member 22b or the condensing portion 4b may be fixed to the inner member 22a by adhesion or welding. Furthermore, the heat pipe 4 may be fixed to either the outer members 22b or the inner member 22a.

In one or more embodiments, the heat dissipation flange portion 22 is arranged separately from the body portion 1, and is connected to the body portion 1 to be supported by the heat pipe 4.

In addition, the heat dissipation flange portion 22 is separated from the cable flange portion 21 in the axial direction.

Next, the operation of the cable drum 10 constituted as described above will be described.

The body portion 1 of the cable drum 10 is heated by the cable being used while being wound around the cable drum 10. In the evaporating portion 4a of the heat pipe 4 in contact with the inner circumferential surface of the body portion 1, the liquid-phase working fluid within the wick is heated via the wall surface of the container to evaporate. As the working fluid evaporates, the pressure of the gas inside the container on the side of the evaporating portion 4a rises. Consequently, the working fluid turned into the gas phase moves toward the side of the condensing portion 4b through the interior space of the container.

The heat dissipation flange portion 22 receives heat from the condensing portion 4b of the heat pipe 4 and passes the received heat to the outside air. Accordingly, the gas-phase working fluid that has reached the condensing portion 4b loses heat via the wall surface of the container to be condensed, and transforms into liquid droplets that stick to the wall surface of the container. The liquid droplets of the working fluid penetrate the pores of the wick by capillary force. The liquid-phase working fluid within the pores of the wick moves to the side of the evaporating portion 4a of the wick by the capillary force.

The liquid-phase working fluid that has reached the evaporating portion 4a in the wick is heated again via the wall surface of the container in contact with the inner circumferential surface of the body portion 1 and evaporates from the surface of the wick in the evaporating portion 4a. The working fluid that has evaporated and turned into the gas phase moves again to the side of the condensing portion 4b through the interior space of the container. In this manner, the heat pipe 4 can repeatedly utilize the phase transition of the working fluid between the liquid phase and the gas phase to repeatedly transport the heat recovered on the side of the evaporating portion 4a to the side of the condensing portion 4b of the heat pipe 4.

As described above, according to the cable drum of one or more embodiments, the evaporating portion 4a of the heat pipe 4 is disposed in the body portion 1 and the condensing portion 4b is disposed in the flange portion 2. With this structure, when the cable wound around the body portion 1 generates heat, the heat of the body portion 1 can be efficiently transferred to the flange portion 2 by the heat pipes 4. In addition, it is possible to efficiently dissipate the transferred heat from the flange portion 2. Therefore, it is possible to efficiently cool the wound cable without connecting, for example, a blower.

Here, when heat is applied to an intermediate portion between the evaporating portion 4a and the condensing portion 4b in the heat pipe 4, there is a possibility of a phenomenon in which the working fluid evaporates at the intermediate portion and unexpectedly backflows to the side of the evaporating portion 4a occurring. Thus, by arranging the body portion 1 and the heat dissipation flange portion 22 apart from each other, in one or more embodiments, it is possible to suppress the application of heat to the intermediate portion of the heat pipe 4 and to restrain the occurrence of the above phenomenon. Additionally, it is also possible to suppress the direct heat transfer from the body portion 1 to the heat dissipation flange portion 22.

In addition, the cable flange portion 21 requiring strength and the heat dissipation flange portion 22 requiring heat dissipation properties are set as independent bodies, and accordingly, the respective requirements are satisfied with ease. Furthermore, the heat transfer between the cable flange portion 21 and the heat dissipation flange portion 22 can be suppressed.

Note that the technical scope of the present invention is not limited to the above-described embodiments and various changes can be made without departing from the spirit of the present invention.

For example, in the above embodiments, the L-shaped heat pipe 4 is adopted, and the evaporating portions 4a of the two heat pipes 4 are arranged to oppose each other in the axial direction. The shape of the heat pipe 4 is not restricted to this L shape, and a C-shaped heat pipe having a shape obtained by integrating two L-shaped heat pipes 4 arranged to oppose each other in the axial direction may be adopted. In this case, the evaporating portion 4a of the heat pipe 4 may extend over the entire length in the axial direction of the body portion 1 such that the condensing portions 4b extend toward the outer side in the radial direction from the two end portions in the axial direction of the evaporating portion 4a.

Furthermore, in order to enhance the heat exchange efficiency of the heat dissipation flange portion 22, a concavo-convex shape may be formed on the surface of the heat dissipation flange portion 22.

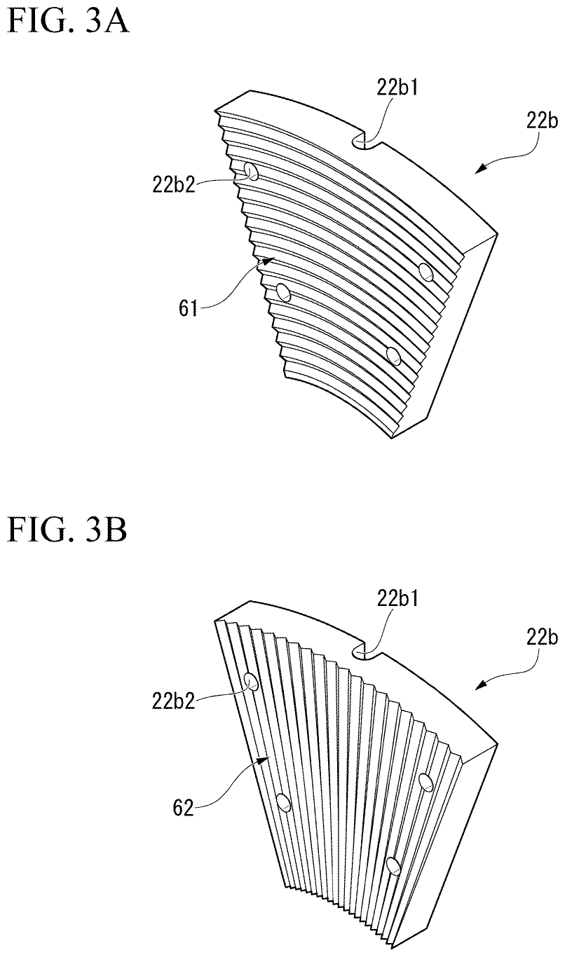

For example, as illustrated in FIG. 3A, a plurality of groove portions 61 extending in the circumferential direction may be formed on the surface on the outer side in the axial direction of the outer member 22b. In this case, by enlarging the surface area of the heat dissipation flange portion 22, the heat of the condensing portion 4b of the heat pipe 4 can be efficiently dissipated. Furthermore, when the cable drum 10 is rotated about the center axis O of the body portion 1, heat can be dissipated efficiently by the air traveling through the plurality of groove portions 61 extending in the circumferential direction.

Alternatively, as illustrated in FIG. 3B, a plurality of groove portions 62 extending in the radial direction may be formed on the surface on the outer side in the axial direction of the outer member 22b. Also, in this case, by enlarging the surface area of the heat dissipation flange portion 22, the heat of the condensing portion 4b of the heat pipe 4 can be efficiently dissipated. Furthermore, when the cable drum 10 is rotated about the center axis O of the body portion 1, heat can be dissipated efficiently because the air surrounding the heat dissipation flange portion 22 can be agitated by the plurality of groove portions 62 extending in the radial direction.

In addition, the outer member 22b illustrated in FIG. 3A and the outer member 22b illustrated in FIG. 3B may be used in combination. Alternatively, the groove portions 61 and 62 may be formed in the inner member 22a (on a surface on the inner side in the axial direction of the heat dissipation flange portion 22), or a concavo-convex shape may be formed by other shapes such as dimples.

Furthermore, the cable drum 10 may not include the cable flange portion 21. In this case, winding collapse may be prevented, for example, using a traverser to wind up the cable.

Meanwhile, although the heat pipe 4 is arranged such that the evaporating portion 4a is in contact with the inner circumferential surface of the body portion 1, the evaporating portion 4a may be arranged, for example, on the outer circumferential side of the body portion 1 so as to be in abutment with or proximity to the cable.

In addition, although the condensing portion 4b is sandwiched between two members of the inner member 22a and the outer member 22b, the condensing portion 4b may be arranged so as to be in contact with or proximity to one member out of the two members 22a and 22b.

Furthermore, the heat dissipation flange portion 22 may not have the inner member 22a such that the condensing portion 4b of the heat pipe 4 is fixed between the cable flange portion 21 and the outer member 22b.

Additionally, in the above-described embodiments, the heat dissipation flange portion 22 is connected to the body portion 1 to be supported by the heat pipe 4. However, for example, the heat dissipation flange portion 22 may be connected to the attachment member 5 to be supported. Alternatively, in a state in which the inner member 22a and the cable flange portion 21 are separated and a space is provided between the inner member 22a and the cable flange portion 21, the heat dissipation flange portion 22 may be connected to the cable flange portion 21 by a connecting member such as a screw to be supported. Alternatively, when the cable drum 10 and the drum shaft are integrated, the heat dissipation flange portion 22 may be connected to the drum shaft to be supported.

Further, within the scope not departing from the spirit of the present invention, it is possible to appropriately replace the constituent elements of the above-described embodiments with well-known constituent elements, and the above-described embodiments and modified examples may also be appropriately combined.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

1: Body portion
2: Flange portion
4: Heat pipe
4a: Evaporating portion
4b: Condensing portion
10: Cable drum
21: Cable flange portion
22: Heat dissipation flange portion
61, 62: Groove portion

1. A cable drum, around which a cable is coiled, comprising:
a body;
a flange; and
a plurality of heat pipes arranged across the body and the flange, wherein
evaporating portions of the plurality of heat pipes are disposed in the body, and
condensing portions of the plurality of heat pipes are disposed in the flange.

2. The cable drum according to claim 1, wherein
the condensing portions are fixed to a heat dissipation flange portion of the flange, and
the body and the heat dissipation flange portion are separated.

3. The cable drum according to claim 2, wherein
the flange includes a cable flange portion that is fixed to the body and that extends from the body to an outer side in a radial direction of the body, and
the heat dissipation flange portion and the cable flange portion are separated in an axial direction of the body.

4. The cable drum according to claim 1, wherein
the condensing portions are fixed to a heat dissipation flange portion of the flange, and
a plurality of groove portions extending in a circumferential direction of the body are formed in the heat dissipation flange portion.

5. The cable drum according to claim 1, wherein
the condensing portions are fixed to a heat dissipation flange portion of the flange, and
a plurality of groove portions extending in a radial direction of the body are formed in the heat dissipation flange portion.
